(19) United States
(12) Patent Application Publication
(10) Pub. No.: US 2023/0187343 A1
(43) Pub. Date: Jun. 15, 2023

(54) TOP VIA INTERCONNECT STRUCTURE WITH TEXTURE SUPPRESSION LAYERS

(71) Applicant: INTERNATIONAL BUSINESS MACHINES CORPORATION, ARMONK, NY (US)

(72) Inventors: Oscar van der Straten, Guilderland Center, NY (US); Koichi Motoyama, Clifton Park, NY (US); Joseph F. Maniscalco, Greenville, SC (US); Kenneth Chun Kuen Cheng, Shatin (HK)

(21) Appl. No.: 17/643,434

(22) Filed: Dec. 9, 2021

(51) Int. Cl. H01L 23/522; H01L 23/532; H01L 21/768

(52) U.S. Cl. CPC H01L 23/5226; H01L 23/53209; H01L 23/53223; H01L 23/53238; H01L 23/53266; H01L 21/76885

(57) ABSTRACT

An interconnect structure and a method of forming the interconnect structure are provided. The interconnect structure includes a metal line layer and a top via layer that each include a plurality of alternating first layers composed of a first metal and second layers composed of a second metal, whereby the second layers are thinner than the first layers.

### BACKGROUND

This disclosure relates generally to integrated circuit fabrication and, more particularly, to interconnect devices.

Back end of line (BEOL) is the portion of integrated circuit fabrication where the individual devices (transistors, capacitors, resisters, etc.) get interconnected with wiring on the wafer, the metallization layer. BEOL generally begins when the first layer of metal is deposited on the wafer. BEOL includes contacts, insulating layers (dielectrics), metal levels, and bonding sites for chip-to-package connections. A via is an electrical connection between layers in a physical electronic circuit that goes through the plane of one or more adjacent layers. In integrated circuit design, a via is a small opening in an insulating oxide layer that allows a conductive connection between different layers.

### SUMMARY

Embodiments relate to an interconnect structure and a method of forming the interconnect structure. According to one aspect, an interconnect structure is provided. The interconnect structure may include a metal line layer and a top via layer that each include a plurality of alternating first layers composed of a first metal and second layers composed of a second metal, whereby the second layers are thinner than the first layers.

According to one aspect, an interconnect structure is provided. The interconnect structure may include a diffusion barrier, a metal line layer above and contacting the diffusion barrier, and a top via layer above and contacting the metal line layer. The metal line layer and top via layer may each include a plurality of alternating first layers composed of a first metal and second layers composed of a second metal, whereby the second layers are thinner than the first layers.

According to another aspect, a method of forming an interconnect structure is provided. The method may include forming a metal line layer and forming a top via layer above and contacting the metal line layer. The metal line layer and the top via layer may each include a plurality of alternating first layers composed of a first metal and second layers composed of a second metal, whereby the second layers are thinner than the first layers.

### BRIEF DESCRIPTION OF THE DRAWINGS

These and other objects, features and advantages will become apparent from the following detailed description of illustrative embodiments, which is to be read in connection with the accompanying drawings. The various features of the drawings are not to scale as the illustrations are for clarity in facilitating the understanding of one skilled in the art in conjunction with the detailed description. In the drawings:

FIGS. 1-9 illustrate the steps of a method of forming an interconnect structure, according to at least one embodiment;

FIG. 1 depicts a cross-sectional view of a process of deposition of a diffusion barrier layer and a metal line layer, according to at least one embodiment;

FIG. 2 depicts a cross-sectional view of a process of deposition of a texture suppression layer on the metal line layer, according to at least one embodiment;

FIG. 3 depicts a cross-sectional view of a process of deposition of alternating conductor layers and texture suppression layers to complete a metal line, according to at least one embodiment;

FIG. 4 depicts a cross-sectional view of a process of deposition of alternating conductor layers and texture suppression layers to complete a top via layer, according to at least one embodiment;

FIG. 5 depicts a cross-sectional view of a process of deposition of a hardmask and photoresist, according to at least one embodiment;

FIG. 6 depicts a cross-sectional view of a process of etching of the hardmask and the conductor layers and texture suppression layers of the top via layer, according to at least one embodiment;

FIG. 7 depicts a cross-sectional view of a process of filling of the etched top via layer with an interlayer dielectric layer, according to at least one embodiment;

FIG. 8 depicts a cross-sectional view of a process of deposition of a hardmask, according to at least one embodiment;

FIG. 9 depicts a cross-sectional view of a process of etching of the conductor layers and texture suppression layers of the metal line layer, as well as filling the surrounding area with dielectric followed by planarization, according to at least one embodiment; and

FIG. 10 depicts an operational flowchart illustrating the steps of fabricating an interconnect device, according to at least one embodiment.

The drawings are not necessarily to scale. The drawings are merely schematic representations, not intended to portray specific parameters. The drawings are intended to depict only typical embodiments. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. Those structures and methods may, however, be embodied in many different forms and should not be construed as limited to the exemplary embodiments set forth herein. Rather, these exemplary embodiments are provided so that this disclosure will be thorough and complete and will fully convey the scope to those skilled in the art. In the description, details of well-known features and techniques may be omitted to avoid unnecessarily obscuring the presented embodiments.

It is understood in advance that although example embodiments of this disclosure are described in connection with a particular integrated circuit architecture, embodiments of this disclosure are not limited to the particular device architectures or materials described in this specification. Rather, embodiments of this disclosure are capable of being implemented in conjunction with any other type of integrated circuit architecture or materials now known or later developed.

For the sake of brevity, conventional techniques related to semiconductor device and integrated circuit fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based integrated circuits are well known and so, in the interest of brevity, many conventional steps will only be mentioned briefly herein or will be omitted entirely without providing the well-known process details.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “an example embodiment,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “overlaying,” “atop,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terminology used herein is for the purpose of describing particular embodiments only and is not intended to be limiting of this disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of this disclosure relate generally to integrated circuit fabrication and, more particularly, to interconnect devices. As previously described, back end of line (BEOL) is the portion of integrated circuit fabrication where the individual devices (transistors, capacitors, resisters, etc.) get interconnected with wiring on the wafer, the metallization layer. BEOL generally begins when the first layer of metal is deposited on the wafer. BEOL includes contacts, insulating layers (dielectrics), metal levels, and bonding sites for chip-to-package connections. A via is an electrical connection between layers in a physical electronic circuit that goes through the plane of one or more adjacent layers. In integrated circuit design, a via is a small opening in an insulating oxide layer that allows a conductive connection between different layers.

For reliable dual damascene interconnects beyond a 15-nanometer critical dimension, both void-free metal feature fill and excellent dimensional control are essential. However, several major challenges exist for sub-15 nm critical dimension dual damascene interconnects with copper as a main conductor. For example, voids, such as sidewall voids, may exist in vias and lines due to poor copper coverage when copper fill is applied to lines and vias. Additionally, due to restricted geometry in damascene features, only small copper grains may be present. Moreover, copper diffusion barriers are becoming dominant in terms of via and line resistance impact. Alternative approaches for sub-15 nanometer critical dimension interconnects include the formation of top vias and lines by patterning a single thick metal layer (e.g., ruthenium) into a connected metal top via-above and a metal line-below.

However, large ruthenium grains typically result in rough line and top via shapes, providing challenges in dimensional control which leads to line and top via resistance variability and shorts between lines. For interconnects smaller than a 15-nanometer critical dimension, metallization structures are needed which can provide limits to grain size in order to allow dimensional and roughness control over lines and top vias.

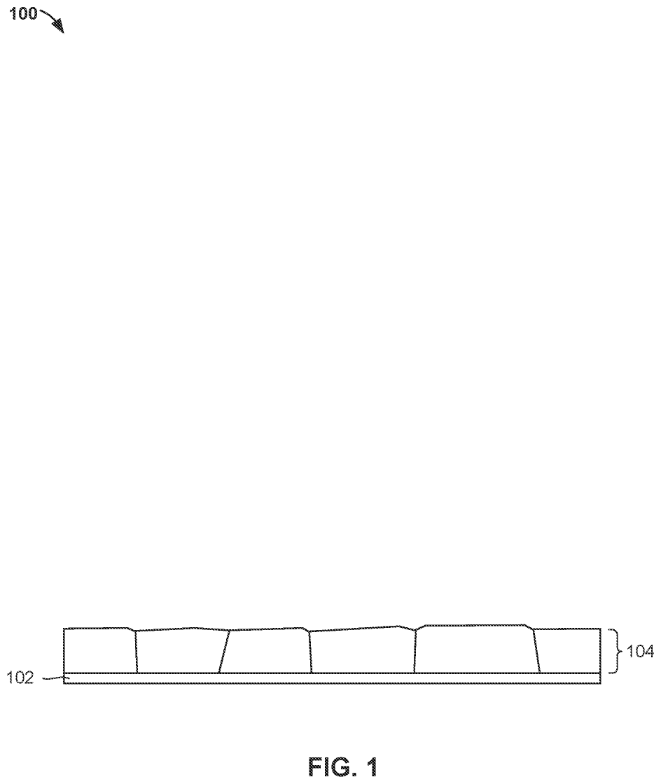

It may be advantageous, therefore, to embed metallic texture suppression layers during formation of a top via structure in order to prevent uncontrolled void growth and roughness in metal lines and top vias. This may be done by depositing multiple conductor and texture suppression layers that are smaller than the overall height of the metal line layer or the top via layer to break up grain boundaries within the metal line layer and top via layer. For example, the conductor layers and the texture suppression layers may be deposited one on top of the other in an alternating fashion. The texture suppression layers may preferably have a similar resistivity to the conductor layers. The texture suppression layers may preferably be thinner than the conductor layers. For example, the texture suppression layers may only be a few angstroms thick. Doing so is specifically designed to control roughness and void growth of the metal line layer and top via layer. One way to fabricate an integrated circuit with texture suppression layers embedded throughout the metal and top via layers is described in detail below by referring to the accompanying drawings FIGS. 1-9.

As used herein, a “top via” refers to the “Vₓ” layer via which electrically couples a line below (an “M” layer) and may also electrically couple to a line above (an “Mₓ₊₁” layer). Embodiments of this disclosure form a metal top via (e.g., Co, Ru) on the metal line below. There may be no barrier metal between the top via and the line metal below. For ease of depiction, the metal lines and top vias are illustrated herein as having a constant width with straight sidewalls. However, it may be appreciated that both the metal line and top via may have a tapered angle in either an upward or downward direction.

Referring now to FIGS. 1-9, exemplary process steps of forming an interconnect device in accordance with one or more embodiments is shown and will now be described in greater detail below. It should be noted that FIGS. 1-9 all represent a cross section view of an interconnect structure 100 depicting the fabrication of an interconnect device.

Referring now to FIG. 1, a cross-sectional view of the interconnect structure 100 after an initial set of processing operations is depicted, according to one or more embodiments. Specifically, FIG. 1 depicts deposition of a liner 102 and a conductor layer 104. The liner 102 may be formed on an underneath device by sputtering, chemical vapor deposition, or atomic layer deposition. The liner 102 may be a conductor such as titanium nitride, titanium aluminum carbide, titanium carbide, or tantalum nitride. In some embodiments, the liner 102 may be comprised of other conductive materials such as aluminum, copper, nickel, cobalt, ruthenium, or combinations thereof. The liner 102 may act as a diffusion barrier to prevent the metal of the conductor layer 104 from diffusing into the underneath device.

The conductor layer 104 may be formed from any type of conductive metal. For example, the conductor layer 104 may be composed of ruthenium, copper, cobalt, molybdenum, tungsten, aluminum, or rhodium. The conductor layer 104 may be deposited on the liner 102 using, for example, chemical vapor deposition, plasma enhanced chemical vapor deposition, physical vapor deposition, or other deposition processes. The conductor layer 104 may be deposited to form a fraction of a metal line layer. For example, the conductor layer 104 may have a thickness of 5 to 40 nm, although other thicknesses are within the contemplated scope of the invention. The conductor layer 104 may form as a plurality of grains having irregular grain boundaries. Moreover, a top surface of the conductor layer 104 may be rough and irregular due to the presence of the plurality of grains.

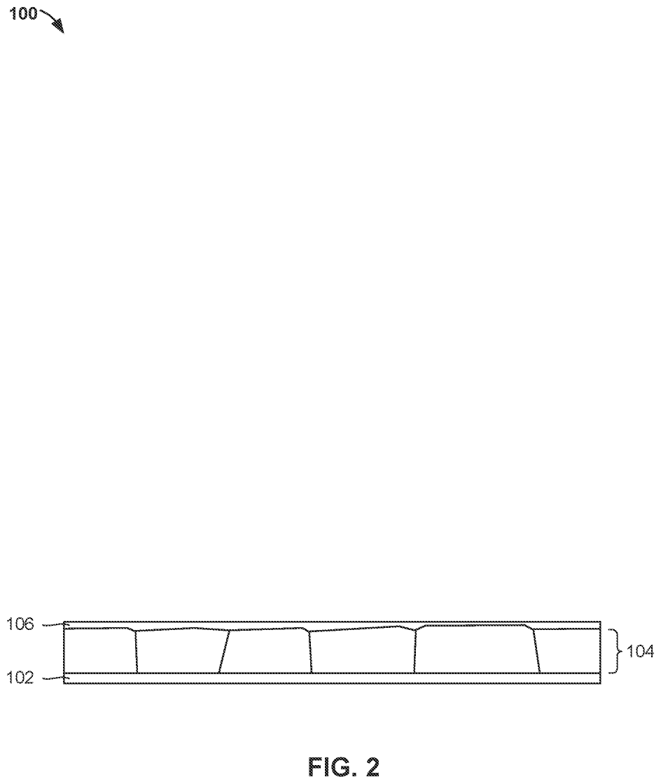

Referring now to FIG. 2, deposition of a texture suppression layer 106 on the conductor layer 104 on the interconnect structure 100 is depicted, according to one or more embodiments. As discussed above, the top surface of the conductor layer 104 may be irregular due to the grains of the conductor layer 104. Thus, the texture suppression layer 106 may be deposited on the top surface of the conductor layer 104 to create a smooth top surface. The texture suppression layer 106 may be deposited by physical vapor deposition (e.g., sputtering), chemical vapor deposition, or atomic layer deposition to form a thickness of about 0.1 nm to about 2 nm, although other thicknesses are within the contemplated scope of this disclosure. The texture suppression layer 106 may be formed as a monolayer of metal. The texture suppression layer 106 may be composed of tantalum, molybdenum, or another metal with a similar resistivity to the metal of which the conductor layer 104 is formed. The respective metals of the conductor layer 104 and the texture suppression layer 106 may have similar resistivities in order to minimize resistance variability throughout the metal line layer. The material for the texture suppression layer 106 may be composed of a material having a high re-sputter rate during deposition, which may enable self-planarization and result in a reduction of roughness of the top surface of the conductor layer 104.

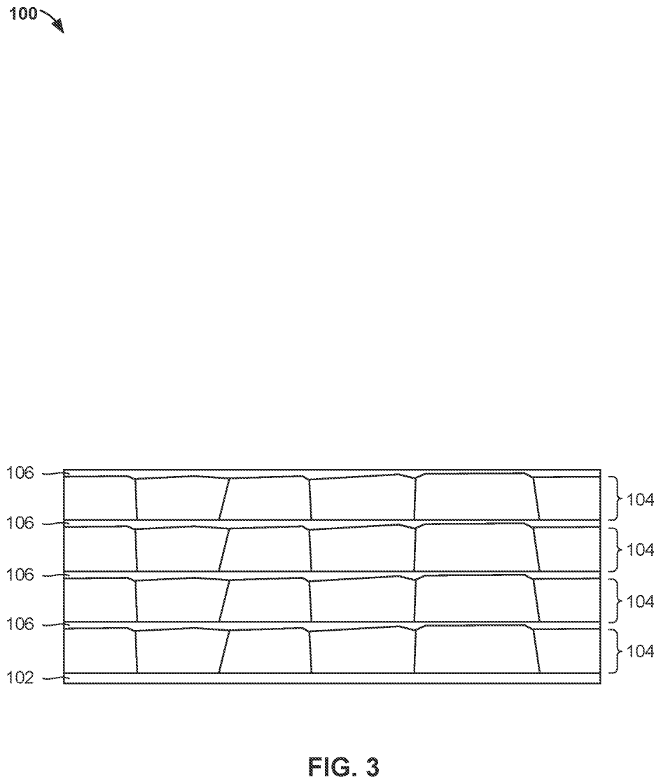

Referring now to FIG. 3, deposition of alternating conductor layers 104 and texture suppression layers 106 to complete a metal line layer (i.e., “Mₓ”) of the interconnect structure 100 is depicted, according to one or more embodiments. As discussed above, the conductor layer 104 may be deposited to form a fraction of the metal line layer. By way of example and not of limitation, FIG. 3 depicts a metal line layer having four pairs of conductor layers 104 and texture suppression layers 106. However, it may be appreciated that the metal line layer may be composed of any number of pairs of conductor layers 104 and texture suppression layers 106. The texture suppression layers 106 may be used to introduce break layers between the conductor layers 104 that may break up the grain structure of the conductor layers 104 and allow for smaller grain sizes in the conductor layers 104. The conductor layers 104 and texture suppression layers 106 may be considered respective first and second sub-layers of the overall metal line layer.

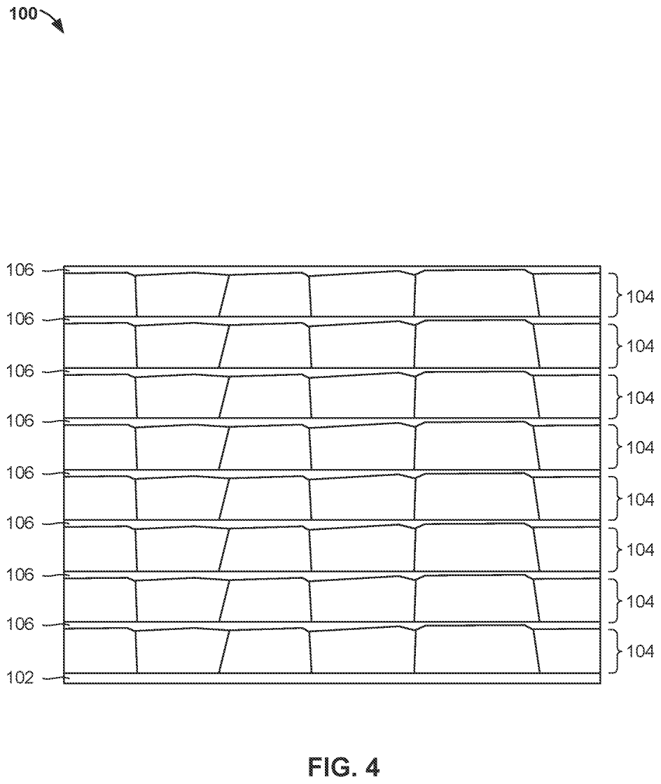

Referring now to FIG. 4, deposition of alternating conductor layers 104 and texture suppression layers 106 to complete a top via layer (i.e., “Vₓ”) of the interconnect structure 100 is depicted, according to one or more embodiments. Similar to the metal line layer, the conductor layer 104 may be deposited to form a fraction of the top via layer. By way of example and not of limitation, FIG. 4 depicts the top via layer having four pairs of conductor layers 104 and texture suppression layers 106. However, it may be appreciated that the top via layer may be composed of any number of pairs of conductor layers 104 and texture suppression layers 106. By depositing multiple alternating layers of the conductor layers 104 and the texture suppression layers 106, smaller grain sizes of the conductor layers 104 with less upper surface roughness may be achieved than if a single conductor layer 104 made up the metal and top via layers. The conductor layers 104 and texture suppression layers 106 may be considered respective first and second sub-layers of the overall top via layer.

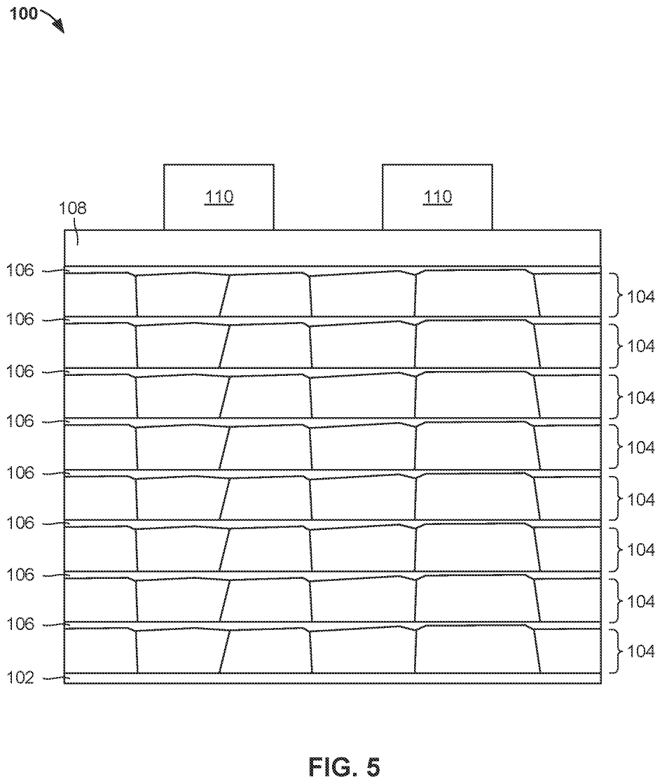

Referring now to FIG. 5, deposition of a hardmask 108 and photoresist 110 on the interconnect structure 100 is depicted, according to one or more embodiments. The hardmask 108 may be composed of titanium nitride, silicon nitride, amorphous silicon, amorphous silicon germanium, or combinations thereof. The hardmask 108 may be deposited using, for example, any suitable deposition process. The photoresist 110 may be a light-sensitive material used in processes, such as photolithography, to form a patterned coating on a surface. The desired hardmask pattern for the hardmask 108 may be formed by removing the areas not protected by the pattern in the photoresist 110.

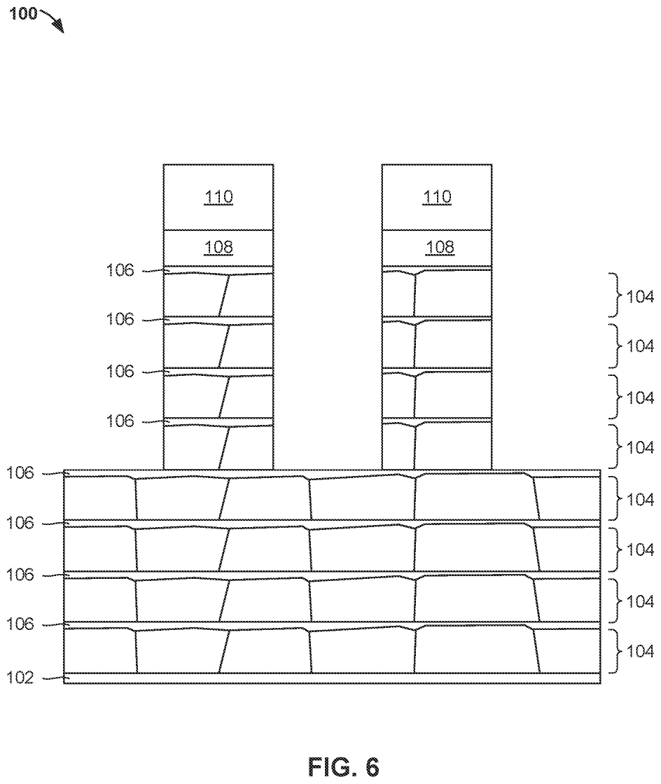

Referring now to FIG. 6, etching of the hardmask 108 and the conductor layers 104 and texture suppression layers 106 of the top via layer of the interconnect structure 100 is depicted, according to one or more embodiments. The hardmask 108 is removed using, for example, reactive ion etching or other etch processes such as wet chemical etching or laser ablation. In general, hardmask 108 is patterned such that hardmask 108 exposes areas of the conductor layers 104 and texture suppression layers 106 of the top via layer that do not coincide with a desired location for a top via.

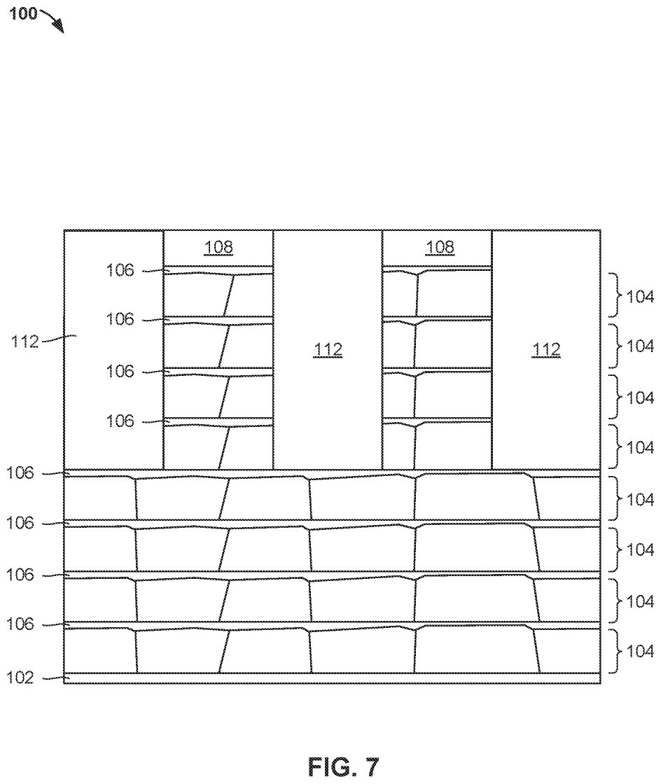

Referring now to FIG. 7, filling of the etched top via layer of the interconnect structure 100 with an interlayer dielectric layer 112 is depicted, according to one or more embodiments. The interlayer dielectric layer 112 may be a non-crystalline solid material such as silicon dioxide, undoped silicate glass, fluorosilicate glass, borophosphosilicate glass, a spin-on low-k dielectric layer, a chemical vapor deposition low-k dielectric layer or any combination thereof. The term “low-k” as used throughout the present application denotes a dielectric material that has a dielectric constant of less than silicon dioxide.

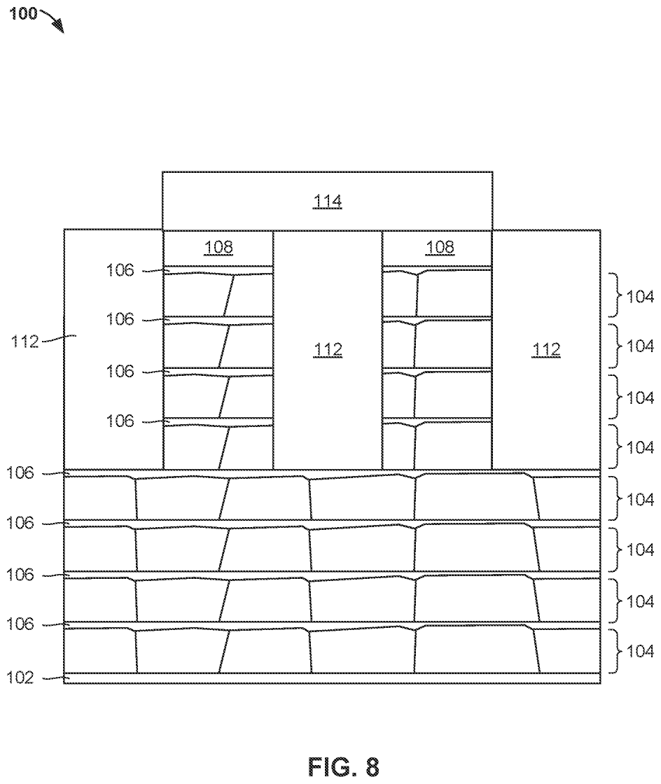

Referring now to FIG. 8, deposition of a hardmask 114 on the interconnect structure 100 is depicted, according to one or more embodiments. The hardmask 114 may be composed of titanium nitride, silicon nitride, amorphous silicon, amorphous silicon germanium, or combinations thereof. The hardmask 114 may be deposited using, for example, any suitable deposition process.

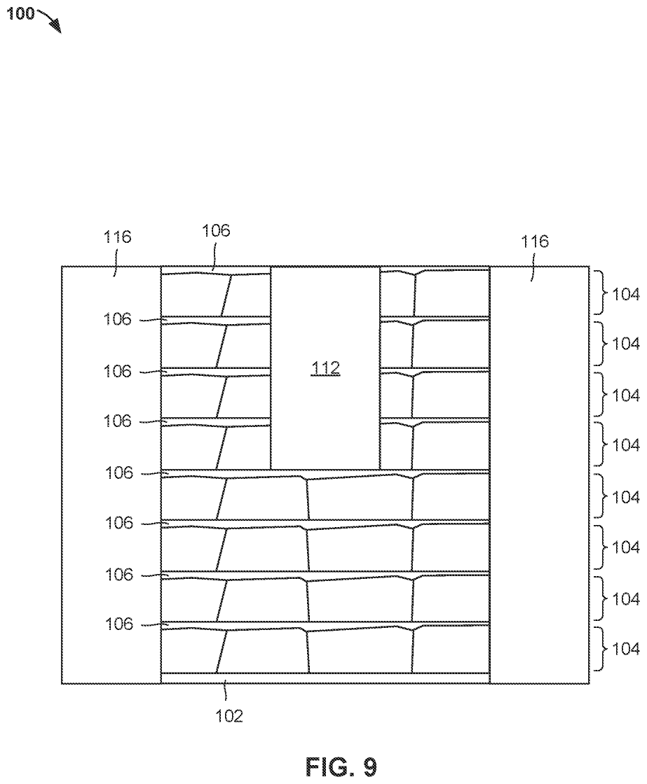

Referring now to FIG. 9, depicts etching of the interlayer dielectric layer 112, the conductor layers 104 and texture suppression layers 106 of the metal line layer, and the liner 102 of the interconnect structure 100 is depicted, according to one or more embodiments. The interlayer dielectric layer 112, the conductor layers 104 and texture suppression layers 106, and the liner 102 may each be etched by respective reactive ion etch processes. As discussed above, reactive ion etching uses chemically reactive plasma, generated by an electromagnetic field, to remove various materials. Subsequent to the etching of the interlayer dielectric layer 112, the conductor layers 104 and texture suppression layers 106 of the metal line layer, and the liner 102, the hardmask 114 may be removed and a dielectric layer 116 may be deposited to surround the conductor layers 104 and texture suppression layers 106 of the metal and top via layers.

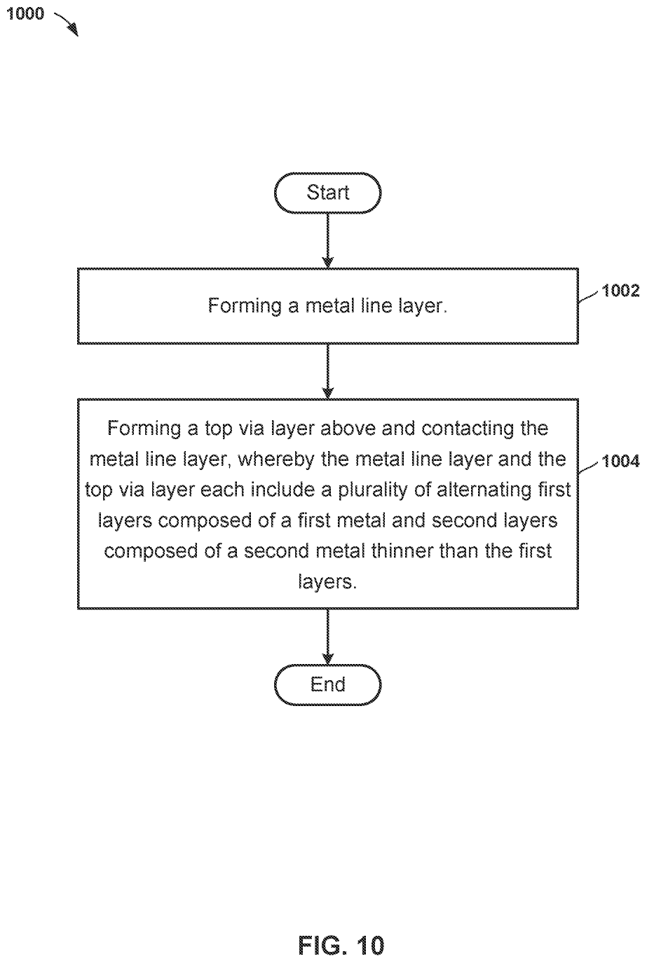

Referring now to FIG. 10, an operational flowchart illustrating the steps of a method 1000 for forming an interconnect structure is depicted.

At 1002, the method 1000 may include forming a metal line layer.

At 1004, the method 1000 may include forming a top via layer above and contacting the metal line layer. The metal line layer and the top via layer each include a plurality of alternating first layers composed of a first metal and second layers composed of a second metal that are thinner than the first layers.

It may be appreciated that FIG. 10 provides only an illustration of one implementation and does not imply any limitations with regard to how different embodiments may be implemented. Many modifications may be made based on design and implementation requirements.

The resulting structure described above is a BEOL metal line and top via interconnect structure that includes a top via structure having alternating conductor layers and texture suppression layers to ensure small grain structure and a smooth surface of the top via structure. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. An interconnect structure comprising:
a metal line layer and a top via layer, each comprising a plurality of alternating first layers composed of a first metal and second layers composed of a second metal, wherein the second layers are thinner than the first layers.

2. The interconnect structure of claim 1, wherein the metal line layer and the top via layer each include at least four first layers and four second layers.

3. The interconnect structure of claim 1, wherein the second layers are monolayers of the second metal.

4. The interconnect structure of claim 1, further comprising:
a dielectric material surrounding the metal line layer and the top via layer.

5. The interconnect structure of claim 1, wherein the first metal and the second metal have a substantially similar resistivity.

6. The interconnect structure of claim 1, wherein the first metal is selected from the group consisting of: ruthenium, copper, cobalt, molybdenum, tungsten, aluminum, or rhodium.

7. The interconnect structure of claim 1, wherein the second metal is tantalum or molybdenum.

8. The interconnect structure of claim 1, wherein the second metal is selected from the group consisting of: tantalum nitride, molybdenum nitride, and tantalum molybdenum nitride.

9. An interconnect structure comprising:
a diffusion barrier;
a metal line layer above and contacting the diffusion barrier; and
a top via layer above and contacting the metal line layer,
wherein the metal line layer and the top via layer each include a plurality of alternating first layers composed of a first metal and second layers composed of a second metal, wherein the second layers are thinner than the first layers.

10. The interconnect structure of claim 9, wherein the metal line layer and the top via layer each include at least four conductor layers and at least four texture suppression layers.

11. The interconnect structure of claim 9, wherein the second layers are monolayers of the second metal.

12. The interconnect structure of claim 9, further comprising:
a dielectric material surrounding the metal line layer and the top via layer.

13. The interconnect structure of claim 9, wherein the first metal and the second metal have a substantially similar resistivity.

14. The interconnect structure of claim 9, wherein the first metal is selected from the group consisting of: ruthenium, copper, cobalt, molybdenum, tungsten, aluminum, or rhodium.

15. The interconnect structure of claim 9, wherein the second metal is tantalum or molybdenum.

16. The interconnect structure of claim 9, wherein the second metal is selected from the group consisting: tantalum nitride, molybdenum nitride, and tantalum molybdenum nitride.

17. A method of forming a structure, comprising:
forming a metal line layer; and
forming a top via layer above and contacting the metal line layer,
wherein the metal line layer and the top via layer each include a plurality of alternating first layers composed of a first metal and second layers composed of a second metal, wherein the second layers are thinner than the first layers.

18. The method of claim 17, wherein the metal line layer and the top via layer each include at least four first layers and at least four second layers.

19. The method of claim 17, wherein the second layers are monolayers of the second metal.

20. The method of claim 17, further comprising:
forming a dielectric material surrounding the metal line layer and the top via layer.
